(19) United States
(12) Patent Application Publication
(10) Pub. No.: US 2026/0247882 A1
(43) Pub. Date: Aug. 20, 2026

(54) SEMICONDUCTOR DEVICE AND METHOD OF FORMING SAME

(71) Applicant: ASM IP Holding B.V., Almere (NL)

(72) Inventors: Tieyi Lu, Chandler, AZ (US); Jiyeon Kim, Mesa, AZ (US); Guannan Chen, Phoenix, AZ (US); Chenxiao Wang, Mesa, AZ (US); Amy You, Tempe, AZ (US); YoungChol Byun, Tempe, AZ (US); Jonathan Bakke, Phoenix, AZ (US); Paul Ma, Scottsdale, AZ (US); Chad Russell Lunceford, Phoenix, AZ (US); Neelam Sheoran, Tempe, AZ (US)

(21) Appl. No.: 19/541,482

(22) Filed: Feb. 17, 2026

Related U.S. Application Data
(60) Provisional application No. 63/760,912, filed on Feb. 20, 2025.

(51) Int. Cl. H10P 14/60; C23C 16/455; H10P 14/694

(52) U.S. Cl. CPC H10P 14/6336; C23C 16/45553; H10P 14/69433

(57) ABSTRACT

A method for forming a semiconductor device. An exemplary method includes optionally forming an oxide layer and forming a passivation layer. Forming the passivation layer includes providing a treatment precursor to the reaction chamber. The treatment precursor can be or include an organic silicon-containing precursor or an organic boron-containing precursor.

### CROSS-REFERENCE TO RELATED APPLICATIONS

This application is a nonprovisional of, and claims priority to and the benefit of, U.S. Provisional Patent Application No. 63/760,912, filed Feb. 20, 2025 and entitled “SEMICONDUCTOR DEVICE AND METHOD OF FORMING SAME,” which is hereby incorporated by reference herein.

### FIELD

The disclosure generally relates to methods of forming electronic devices. More particularly, examples are described that relate to a method for forming a semiconductor device that includes a passivation layer on an oxide layer, to a structure comprising the oxide layer, and to a substrate processing apparatus for forming the oxide layer and the passivation layer.

### BACKGROUND

The use of deposition methods using gaseous precursors in formation of semiconductor devices has led to significant improvements in speed and density of integrated circuits. The use of certain precursors in the formation of semiconductor devices, however, has presented challenge. For example, precursors using halide compounds have proven effective in depositing thin films. However, halide species from the halide compounds may penetrate, thin, or damage surrounding layers (such as oxide layers), resulting in degradation of the surrounding layers. Developing technologies that allow for the use of halide compounds as precursors, while protecting surrounding layers from degradation has been challenging. Thus, there exists a desire for improved deposition methods for protecting surrounding (e.g., oxide) layers from unwanted effects of precursors containing halide compounds.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

Various examples of the method provide for the formation of a passivation layer on an oxide layer to mitigate or prevent damage to the oxide layer from potentially damaging species. Examples described herein provide for the formation of at least part of a buried word line and the treatment of a gate oxide in a buried word line. The methods disclosed herein provide semiconductor devices with a passivation layer and/or treatments to prevent halides or other species from penetrating, thinning, and/or damaging oxide layers of e.g., semiconductor devices.

According to one or more embodiments, a method of forming a semiconductor device is provided. An exemplary method includes providing a substrate in a reaction chamber. In some embodiments, the substrate includes an oxide layer on the surface of the substrate. If the substrate does not comprise an oxide layer, the exemplary method includes forming an oxide layer on the surface of the substrate. The exemplary method continues with forming a passivation layer (e.g., directly) on the oxide layer. In accordance with examples, forming the passivation layer includes providing a treatment precursor to the reaction chamber. The treatment precursor can be or include an organic silicon-containing precursor or an organic boron-containing precursor.

In some embodiments, the oxide layer includes silicon and oxygen. In some embodiments, the oxide layer includes SiO₂. In some embodiments, the oxide layer includes carbon and/or nitrogen. The oxide layer is formed by any suitable method, including oxidation of the surface of the substrate, a chemical vapor deposition process, or a cyclical vapor deposition process. In some embodiments, the oxide layer has a thickness in the range of about 30 Angstroms to about 100 Angstroms, or in the range of about 40 Angstroms to 70 Angstroms.

The organic silicon-containing precursor can include least one silicon-carbon bond. In some embodiments, the silicon-containing precursor includes a carbon ring structure. In some embodiments, the silicon-containing precursor includes a cyclohexane ring. In some embodiments, the silicon-containing precursor includes between 6 and 30 carbon atoms, or between 9 and 18 carbon atoms. In some embodiments, the silicon-containing precursor includes at least two silicon atoms. In some embodiments, the silicon-containing precursor includes at least one ligand with the formula of —Si(R¹)₃, where each R¹ is independently selected from H or C1-C3 alkyl groups. In some embodiments, the silicon-containing precursor includes a compound with formula (i):

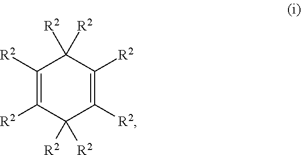

where each R² is independently selected from H, C1-C3 alkyl groups, or ligands with the formula of —Si(R¹)₃, where each R¹ is independently selected from H or C1-C3 alkyl groups. In some embodiments, the silicon-containing precursor includes a compound with formula (ii):

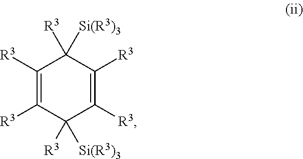

where each R³ is independently selected from H or C1-C3 alkyl groups. By way of examples, the silicon-containing precursor may be represented by formula (iii):

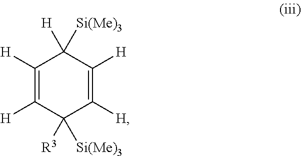

where Me is a methyl group.

The organic boron-containing precursor can include at least one boron-carbon bond. In some embodiments, the boron-containing precursor comprises at least two boron-carbon bonds. In some embodiments, the boron-containing precursor comprises at least three boron-carbon bonds. In some embodiments, the boron-containing precursor comprises a compound with the formula of B(R²)₃, where each R² is independently selected from H or C1-C3 alkyl groups. By way of particular example, the boron-containing precursor comprises triethylborane. In some embodiments, the boron-containing precursor comprises a compound with the formula of B₂(R³)₆, where each R³ is independently selected from H or C1-C3 alkyl groups.

In some embodiments, the passivation layer has a thickness between about 1 Angstrom and 10 Angstroms, or between about 3 Angstroms and about 7 Angstroms. In some embodiments, the passivation layer comprises a surface comprising silicon-carbon bonds or boron-oxygen bonds.

An exemplary method can further include forming a conductive layer. Forming a conductive layer is performed after forming a passivation layer. Forming a conductive layer can include providing a metal halide precursor. In some embodiments, the conductive layer includes forming a metal or metal nitride layer, wherein forming the metal or metal nitride layer comprises providing the metal halide precursor. The conductive layer may be formed by any suitable method, including chemical vapor deposition or cyclical vapor deposition processes. In some embodiments, the conductive layer is formed (e.g., directly) on the passivation layer. In other embodiments, the passivation layer is removed during the step of forming the conductive layer. In these embodiments, the conductive layer is formed (e.g., directly) on the oxide layer. During the formation of the conductive layer, the passivation layer mitigates or prevents migration of halides from the metal halide precursor to and/or into the oxide layer.

In some embodiments, the metal halide precursor comprises a metal selected from the list consisting of W, V, Nb, Ti, or Mo. In some embodiments, the metal halide comprises F, Cl, Br, or I. In some embodiments, the metal halide precursor consists of one or more metals and one or more halides.

In some embodiments, the conductive layer comprises a metal layer, such as metallic W, V, Nb, Ti, or Mo. In some embodiments, forming the metal layer comprises pulsing a metal halide precursor and pulsing a reducing reactant.

In some embodiments, the conductive layer comprises a metal nitride layer, such as a nitride of W, V, Nb, Ti, or Mo. In some embodiments, forming the metal nitride layer comprises pulsing a metal halide precursor and pulsing a nitriding reactant.

In accordance with further examples of the disclosure, a device is formed using a method and/or include a structure as described herein.

In accordance with yet further exemplary embodiments of the disclosure, a system is provided for performing a method and/or for forming a structure as described herein.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWINGS

FIG. 1 illustrates a method for forming a semiconductor device in accordance with one or more embodiments of the disclosure;

FIG. 2 illustrates a method for forming a conductive layer in accordance with one or more embodiments of the disclosure;

FIG. 3 illustrates another method for forming a conductive layer in accordance with one or more embodiments of the disclosure;

FIG. 4 illustrates an example of a substrate processing apparatus in accordance with one or more examples of the disclosure;

FIG. 5 illustrates an exemplary structure in accordance with one or more examples of the disclosure;

FIG. 6 illustrates another exemplary structure in accordance with one or more examples of the disclosure;

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods, structures, devices, and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As used herein, the term “and/or” includes any and all combinations of one or more of the associated listed items. Unless otherwise noted, expressions such as “at least one of,” when preceding a list of elements, modify the entire list of elements and do not necessarily modify the individual elements of the list. As used herein, the singular forms “a,” “an,” and “the” are intended to include the singular and plural forms as well, unless the context indicates otherwise.

As used herein, the term “substrate” can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as Group III-V or Group II-VI semiconductors, and can include one or more layers overlying or underlying the bulk material. By way of example, a substrate can include silicon, or silicon-germanium.

In some embodiments, “film” refers to a layer extending in a direction perpendicular to a thickness direction. In some embodiments, “layer” refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. The layer or film can be continuous- or not. Further, a single film or layer can be formed using one or more deposition cycles.

As used herein, the term “structure” can refer to a partially or completely fabricated device structure. By way of examples, a structure can be a substrate or include a substrate with one or more layers and/or features formed thereon.

As used herein, the term “overlying” can refer to two films in (e.g., direct) contact with each other.

As used herein, the term “cyclical deposition process” or “cyclic deposition process” can refer to a vapor deposition process in which deposition cycles, typically a plurality of consecutive deposition cycles, are conducted in a process chamber. Cyclic deposition processes can include, for example, cyclic chemical vapor deposition (CCVD) and/or atomic layer deposition (ALD) processes.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. For example, values of variables may include +/−20%, or +/−10%, or +/−5%, or +/−1%, or +/−0% of the value of the listed variable. Further, in this disclosure, the terms “comprising,” “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

In some embodiments, the term “conductive” or “conductive material” can refer to a material with an electrical resistivity less than 300 μΩ·cm, or less than 100 μΩ·cm, or less than 30μΩ·cm.

As used herein, “metal” or “metal layer” can refer to a material that consists or, or consists essentially of, one or more metals.

In accordance with various examples, a carrier and/or inert gas can be co-flowed throughout any methods or during any of the sub-steps of methods disclosed herein. By way of example, a carrier and/or an inert gas can be one or more of helium, argon, or nitrogen.

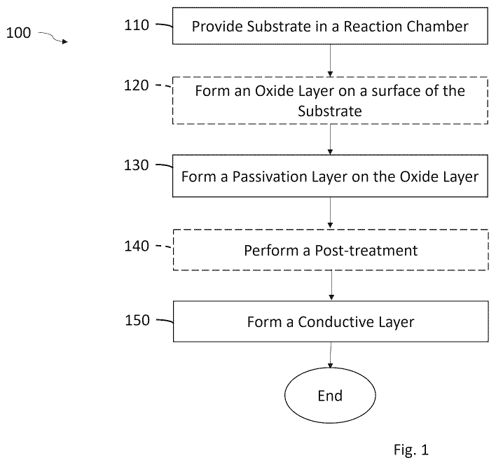

FIG. 1 illustrates a method 100 for forming a semiconductor device in accordance with exemplary embodiments of the disclosure. Method 100 includes the step of providing a substrate within a reaction chamber (step 110), optionally forming an oxide layer on a surface of the substrate (step 120), forming a passivation layer on the oxide layer (step 130), optionally performing a post-treatment (step 140), and forming a conductive layer (step 150). In some embodiments, the semiconductor device is a DRAM device and/or includes a buried word line.

During step 110, a substrate is provided into a reaction space in a reaction chamber. In accordance with examples of the disclosure, the reaction chamber can form part of a chemical vapor deposition reactor, such as a chemical vapor deposition (CVD) reactor, an atomic layer deposition (ALD) reactor, or the like. Various steps of methods described herein can be performed within a single reaction chamber or can be performed in multiple reaction chambers, such as reaction chambers of a cluster tool.

During step 110, the substrate can be brought to a desired temperature and/or the reaction space can be brought to a desired pressure, such as a temperature and/or pressure suitable for subsequent steps. By way of examples, a temperature (e.g., of a substrate, a substrate support, or an environment) within a reaction space can be between about 0° C. and about 500° C., or between about 250° C. and about 425° C. By way of examples, a pressure within a reaction space can be less than 760 torr, or between about 1 torr and 500 torr, or between about 1 torr and about 100 torr.

In some embodiments, the substrate comprises an oxide layer on the surface of the substrate. If the substrate does not include an oxide layer material, the method 100 optionally includes forming an oxide layer on the substrate 120. In some embodiments, the oxide layer comprises silicon and oxygen. In some embodiments, the oxide layer comprises SiO₂. In some embodiments, the oxide layer includes carbon and/or nitrogen. The oxide layer can be formed by any suitable method, such as oxidation of the surface of the substrate, a chemical vapor deposition process, or a cyclical vapor deposition process. In some embodiments, the oxide layer has a thickness in the range of about 30 Angstroms to about 100 Angstroms, or in the range of about 40 Angstroms and about 70 Angstroms. In some embodiments, the oxide layer is a gate oxide layer.

The method 100 continues with forming a passivation layer (e.g., directly) on the oxide layer (step 130). In some embodiments, forming a passivation layer comprises providing a treatment precursor to the reaction chamber.

In some embodiments, the treatment precursor includes an organic silicon-containing precursor comprising at least one silicon-carbon bond. In some embodiments, the silicon-containing precursor includes a carbon ring structure. In some embodiments, the silicon-containing precursor includes a cyclohexane ring. In some embodiments, the silicon-containing precursor includes between 6 and 30 carbon atoms, or between 9 and 18 carbon atoms. In some embodiments, the silicon-containing precursor includes at least two silicon atoms. In some embodiments, the silicon-containing precursor includes at least one ligand with the formula of —Si(R¹)₃, where each R¹ is independently selected from H or C1-C3 alkyl groups. In some embodiments, the silicon-containing precursor includes a compound with formula (i):

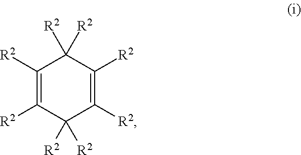

where each R² is independently selected from H, C1-C3 alkyl groups, or ligands with the formula of —Si(R¹)₃, where each R¹ is independently selected from H or C1-C3 alkyl groups. In some embodiments, the silicon-containing precursor includes a compound with formula (ii):

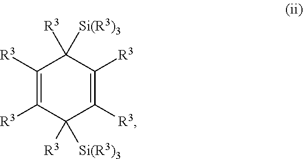

where each R³ is independently selected from H or C1-C3 alkyl groups. By way of examples, the silicon-containing precursor may be represented by formula (iii):

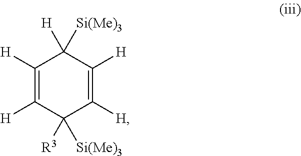

where Me is a methyl group.

In some embodiments, the treatment precursor includes an organic boron-containing precursor comprising at least one boron-carbon bond. In some embodiments, the boron-containing precursor comprises at least two boron-carbon bonds. In some embodiments, the boron-containing precursor comprises at least three boron-carbon bonds. In some embodiments, the boron-containing precursor comprises a compound with the formula of B(R⁴)₃, where each R⁴ is independently selected from H or C1-C3 alkyl groups. In some embodiments, the boron-containing precursor comprises triethylborane. In some embodiments, the boron-containing precursor comprises a compound with the formula of B₂(R⁵)₆, where each R⁵ is independently selected from H or C1-C3 alkyl groups.

In some embodiments, the passivation layer has a thickness between about 1 Angstrom and 10 Angstroms, or between about 3 Angstroms and about 7 Angstroms. In some embodiments, the passivation layer comprises a surface comprising silicon-carbon bonds or boron-oxygen bonds.

The passivation layer mitigates or prevents the penetration, thinning, or damage from the halides or other species to the oxide layer that would otherwise occur. In some embodiments, a prevalence of silicon-carbon bonds or boron-oxygen bonds on the surface of the passivation layer may mitigate or prevent migration of halides or other species through the passivation layer. In some embodiments, halide species or other species react with the passivation layer to form species that may be in gaseous form, which may diffuse away from the surface of the substrate. In some embodiments, the species may then be purged from the reaction chamber. Therefore, in some embodiments, the passivation layer may be at least partially removed when exposed to halides or other species.

Method 100 optionally continues with performing a post-treatment 140.

In some embodiments, performing a post-treatment comprises providing a nitrogen and fluorine plasma to the reaction chamber. In some embodiments, the nitrogen and fluorine plasma is a direct plasma or a remote plasma. In some embodiments, the nitrogen and fluorine plasma is formed using NF₃, and optionally one or more inert gases. The nitrogen and fluorine plasma may remove impurities from the surface of the oxide layer.

In some embodiments, performing a post-treatment comprises providing a hydrogen reactant to the reaction chamber. In some embodiments, the hydrogen reactant comprises H₂, NH₃, and/or N₂H₂, and optionally one or more inert gases. In some embodiments, performing a post-treatment comprises providing a nitrogen and fluorine plasma to the reaction chamber followed by providing a hydrogen reactant to the reaction chamber.

The method 100 continues forming a conductive layer 150. Forming a conductive layer 150 is performed after forming a passivation layer 130. Forming a conductive layer 150 comprises providing a metal halide precursor. The conductive layer may be formed by any suitable method, including, for example, chemical vapor deposition or cyclical vapor deposition processes. In some embodiments, the passivation layer is at least partially removed during the step of forming the conductive layer 150. In some embodiments, the conductive layer is formed (e.g., directly) on the passivation layer. In other embodiments, the passivation layer is removed during the step of forming the conductive layer 150. In these embodiments, the conductive layer is formed (e.g., directly) on the oxide layer.

In some embodiments, the conductive layer includes forming a metal or metal nitride layer, wherein forming the metal or metal nitride layer comprises providing the metal halide precursor. In some embodiments, the metal halide precursor comprises a metal selected from the list consisting of W, V, Nb, Ti, or Mo. In some embodiments, the metal halide comprises one or more of F, Cl, Br, or I. In some embodiments, the metal halide precursor consists of one or more of metals and one or more of halides. In some embodiments, the conductive layer comprises a metal layer, such as metallic W, V, Nb, Ti, or Mo. In some embodiments, the conductive layer comprises a metal nitride layer, such as a nitride of W, V, Nb, Ti, or Mo.

During step 150, the substrate can be brought to a desired temperature and/or the reaction space can be brought to a desired pressure, such as a temperature and/or pressure suitable for subsequent steps. By way of examples, a temperature (e.g., of a substrate, a substrate support, or an environment) within a reaction space can be between about 0° C. and about 500° C., or between about 250° C. and about 425° C. By way of examples, a pressure within a reaction space can be less than 760 torr, or between about 1 torr and 500 torr, or between about 1 torr and about 100 torr.

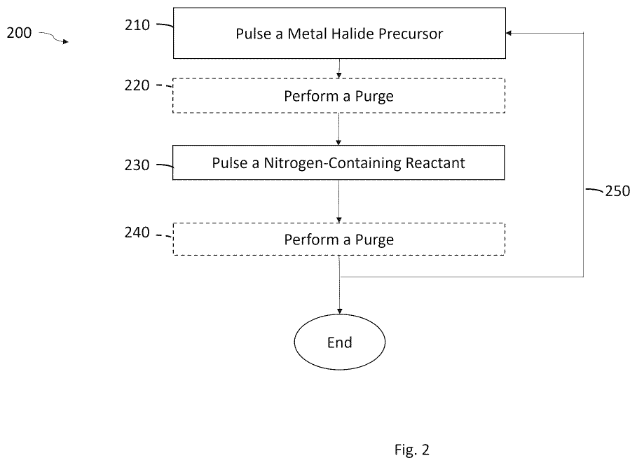

FIG. 2 illustrates a method 200 suitable for step 150 in FIG. 1. Method 200 may produce a conductive layer comprising a metal nitride layer. Method 200 comprises pulsing a metal halide precursor 210, optionally performing a purge 220, pulsing a nitrogen-containing reactant 230, optionally performing a purge 240, and optionally repeating the steps one or more times (loop 250). The sub-steps 210-240 of method 200 may be performed in any order. Each sub-step 210-240 of method 240 may be performed once or a plurality of times. Examples of nitrogen-containing reactants include nitrogen (N2), ammonia, hydrazine, and nitrous oxide. Examples of particular metal halide precursors include MoCl₅, WCl₆, VCl₅, TiCl₄, and NbCl₅.

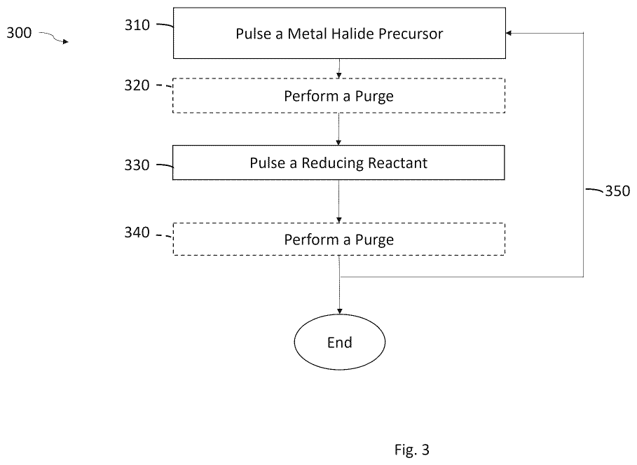

FIG. 3 illustrates another method 300 suitable for step 150 in FIG. 1. Method 300 may produce a conductive layer comprising a metal. Method 300 comprises pulsing a metal halide precursor 310, optionally performing a purge 320, pulsing a reducing reactant 330, optionally performing a purge 340, and optionally repeating the steps one or more times (loop 350). The sub-steps 310-340 of method 300 may be performed in any order. Each sub-step 310-340 of method 340 may be performed once or a plurality of times. Examples of reducing reactants include hydrogen (H₂), carbon monoxide, and diborane. Examples of particular metal halide precursors include MoCl₅, WCl₆, VCl₅, TiCl₄, and NbCl₅.

Various steps of methods described herein can be performed within a single reaction chamber or can be performed in multiple reaction chambers, such as reaction chambers of a cluster tool. In some embodiments, the method 100 may take place in a single reaction space. In some embodiments, one or more substeps of method 100 may take place in a different reaction space or a different reaction chamber.

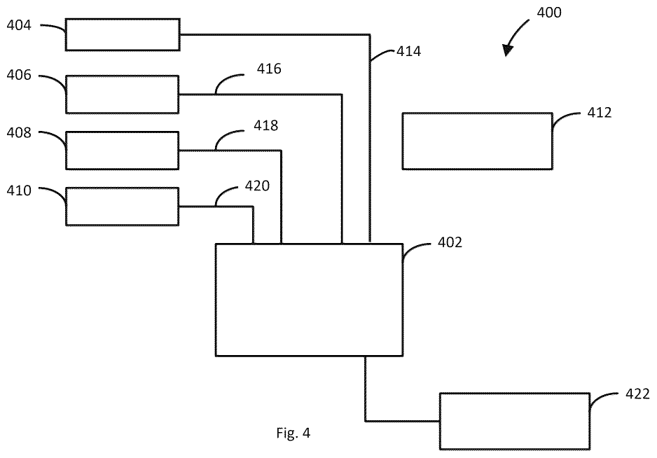

FIG. 4 illustrates an example of a substrate processing apparatus 400 in accordance with one or more examples of the disclosure. Apparatus 400 can be used to perform a method as described herein and/or form a structure or device portion as described herein.

In the illustrated example, apparatus 400 includes one or more reaction chambers 402, a treatment precursor gas source 404, an oxygen-containing gas source 406, a metal halide precursor source 408, a nitrogen-containing or reducing reactant gas source 410, an exhaust source 422, and a controller 412.

Reaction chamber 402 can include any suitable reaction chamber, such as an atomic layer deposition (ALD) or chemical vapor deposition (CVD) reaction chamber.

Treatment precursor gas source 404 can include a vessel and one or more treatment precursors as described herein-alone or mixed with one or more carrier (e.g., inert) gases. Oxygen-containing gas source 406 can include a vessel and one or more oxygen-containing gases that may be used to form an oxide layer as described herein-alone or mixed with one or more carrier (e.g., inert) gases. Metal halide precursor source 408 can include a vessel and one or more metal halide precursors as described herein-alone or mixed with one or more carrier gases. Nitrogen-containing or reducing reactant gas source 410 can include one or more nitrogen-containing or reducing reactant gases as described herein. Although illustrated with four gas sources 404-410, apparatus 400 can include any suitable number of gas sources. Gas sources 404-410 can be coupled to reaction chamber 402 via lines 414-420, which can each include flow controllers, valves, heaters, and the like.

Exhaust source 422 can include one or more vacuum pumps.

Controller 412 includes electronic circuitry and software to selectively operate valves, manifolds, heaters, pumps, and other components included in the apparatus 400. Such circuitry and components operate to introduce precursors, reactants, and gases from the respective sources 404-410. Controller 412 can control timing of gas pulse sequences, temperature of the substrate and/or reaction chamber, pressure within the reaction chamber, and various other operations to provide proper operation of the apparatus 400. Controller 412 can include control software to electrically or pneumatically control valves to control flow of precursors, reactants, and purge gases into and out of the reaction chamber 402. Controller 412 can include modules such as a software or hardware component, e.g., a FPGA or ASIC, which performs certain tasks. A module can advantageously be configured to reside on the addressable storage medium of the control system and be configured to execute one or more processes or methods, as described herein.

Other configurations of apparatus 400 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into reaction chamber 402. Further, as a schematic representation of a system, many components have been omitted for simplicity of illustration, and such components may include, for example, various valves, manifolds, purifiers, heaters, containers, vents, and/or bypasses. In some embodiments, the apparatus 400 includes a remote plasma unit, or the reaction chamber includes structures suitable for generating a plasma within the reaction chamber.

During operation of apparatus 400, substrates, such as semiconductor wafers (not illustrated), are transferred from, e.g., a substrate handling system to reaction chamber 402. Once substrate(s) are transferred to reaction chamber 402, one or more gases from gas sources 404-410, such as precursors, reactants, carrier gases, and/or purge gases, are introduced into reaction chamber 402.

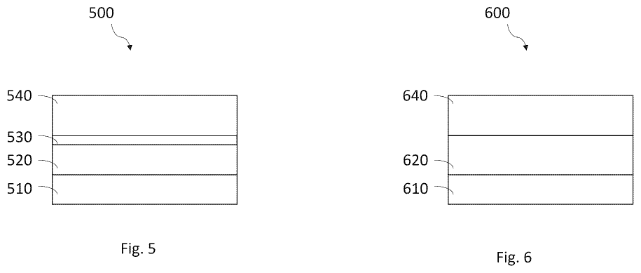

FIG. 5 illustrates a structure/a portion of a device 500 in accordance with additional examples of the disclosure. Device or structure 500 includes a substrate 510, an oxide layer 520, a passivation layer 530, and a conductive layer 540. The oxide layer 520 may be formed by a method described in this disclosure. In some embodiments, the oxide layer 520 comprises a silicon oxide (e.g., SiOₓ or SiO₂). In some embodiments, the oxide layer further comprises carbon and/or nitrogen. The oxide layer 520 may have a thickness between about 30 Angstroms to about 100 Angstroms. The passivation layer 530 may be formed by a method described in this disclosure. In some embodiments, the passivation layer 530 comprises a surface comprising silicon-carbon bonds or boron-oxygen bonds. In some embodiments, the passivation layer 530 comprises a chemisorbed species of a treatment precursor, as described herein. In some embodiments, the passivation layer 530 has a thickness of about 1 Angstrom and about 10 Angstroms. In some embodiments, the passivation layer 530 is disposed directly on the oxide layer 520. The conductive layer 540 may be formed by a method described in this disclosure. In some embodiments, the conductive layer 540 comprises a metal or a metal nitride, such as titanium nitride. The conductive layer 540 may have a thickness between about 3 Angstroms and about 100 Angstroms, or about 5 Angstroms and 15 Angstroms. The conductive layer 540 is disposed directly on the passivation layer 530. In some embodiments, device or structure 500 may comprise at least part of a buried wordline.

FIG. 6 illustrates another structure/a portion of a device 600 in accordance with additional examples of the disclosure. Device or structure 600 includes a substrate 610, an oxide layer 620, and a conductive layer 640. Device or structure 600 may be formed using the methods described herein where the passivation layer is removed while forming the conductive layer. Device or structure 600 is substantially identical to device or structure 500 except that device or structure 600 lacks a passivation layer. In some embodiments, the conductive layer 640 is disposed directly on the oxide layer 620 or the passivation layer may not be visible. In some embodiments, device or structure 600 comprises at least part of a buried wordline.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method for forming a semiconductor device, the method comprising:
providing a substrate in a reaction chamber, wherein the substrate comprises an oxide layer on a surface of the substrate; and
forming a passivation layer on the oxide layer,
wherein forming the passivation layer comprises providing a treatment precursor to the reaction chamber, wherein the treatment precursor comprises an organic silicon-containing precursor comprising at least one silicon-carbon bond or an organic boron-containing precursor comprising at least one boron-carbon bond.

2. The method of claim 1, further comprising providing a metal halide precursor after forming the passivation layer.

3. The method of claim 2, further comprising forming a conductive layer, wherein forming the conductive layer comprises providing the metal halide precursor.

4. The method of claim 3, wherein the passivation layer is removed during forming the conductive layer.

5. The method of claim 2, wherein the passivation layer prevents migration of halides from the metal halide precursor into the oxide layer.

6. The method of claim 1, wherein the passivation layer has a thickness between about 1 Angstrom and 10 Angstroms.

7. The method of claim 1, wherein the passivation layer comprises a surface comprising silicon-carbon bonds or boron-oxygen bonds.

8. The method of claim 1, wherein the oxide layer comprises silicon and oxygen.

9. The method of claim 8, wherein the oxide layer further comprises carbon or nitrogen.

10. The method of claim 2, further comprising performing a treatment step comprising providing a nitrogen and fluorine plasma or providing a hydrogen reactant to the reaction chamber.

11. The method of claim 2, wherein the metal halide precursor comprises a metal selected from one or more of W, V, Nb, Ti, or Mo.

12. The method of claim 1, wherein the treatment precursor comprises a compound with a formula of BR₃ or B₂R₆, where each R is independently selected from H and C1-C3 alkyl groups, and wherein at least one R is a C1-C3 alkyl group.

13. The method of claim 12, wherein the treatment precursor comprises triethylborane.

14. The method of claim 1, wherein the treatment precursor comprises a cyclohexane ring.

15. The method of claim 1, wherein the treatment precursor comprises a compound with formula (i): 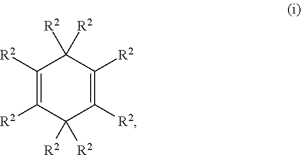
where each R² is independently selected from H, C1-C3 alkyl groups, or ligands with the formula of —Si(R¹)₃, where each R¹ is independently selected from H or C1-C3 alkyl groups.

16. A semiconductor device comprising a buried word line, wherein the buried word line is formed at least partially using a process comprising the method of claim 1.

17. A method for forming a semiconductor device, the method comprising:
providing a substrate comprising a surface in a reaction chamber;
forming an oxide layer on the surface of the substrate; and
forming a passivation layer on the oxide layer,
wherein forming the passivation layer comprises providing a treatment precursor to the reaction chamber, wherein the treatment precursor comprises an organic silicon-containing precursor comprising at least one silicon-carbon bond or an organic boron-containing precursor comprising at least one boron-carbon bond.

18. A semiconductor device comprising
a substrate surface;
an oxide layer disposed directly on the substrate surface;
a passivation layer disposed directly on the oxide layer, wherein the passivation layer comprises silicon-carbon bonds or boron-oxygen bonds; and
a conductive layer disposed directly on the passivation layer, wherein the conductive layer comprises a metal or a metal nitride.

19. The semiconductor device of claim 18, wherein the passivation layer has a thickness between about 1 Angstrom and 10 Angstroms.

20. The semiconductor device of claim 18, wherein the oxide layer has a thickness in the range of 30 Angstroms to 100 Angstroms.
